(19) United States
(12) Patent Application Publication
(10) Pub. No.: US 2026/0181793 A1
(43) Pub. Date: Jun. 25, 2026

(54) DISPLAY APPARATUS

(71) Applicant: LG DISPLAY CO., LTD., Seoul (KR)

(72) Inventor: Jaegyu LEE, Chilgok-gun (KR)

(73) Assignee: LG DISPLAY CO., LTD., Seoul (KR)

(21) Appl. No.: 19/195,271

(22) Filed: Apr. 30, 2025

(30) Foreign Application Priority Data
Dec. 23, 2024 (KR) 10-2024-0193950

(51) Int. Cl. H05K 5/02

(52) U.S. Cl. CPC H05K 5/02

(57) ABSTRACT

The present disclosure relates to a display apparatus in which it is possible to solve a heat generation problem of a driving chip (D-IC) and a short generation problem between components of a printed circuit board (S-PCB). In the display apparatus, a driving chip may be disposed on a display panel in a non-active area, a metal plate may be disposed under the display panel, a bending metal plate may be disposed under the metal plate through a first adhesive layer, a printed circuit board may be disposed under the bending metal plate, one side of a bending insulating layer may be disposed on one side of the bending metal plate, the other side of the bending insulating layer may be disposed under the printed circuit board, and the bending insulating layer may be bent to surround the bending metal plate outward in a bending area.

### CROSS REFERENCE TO RELATED APPLICATION

Pursuant to 35 U.S.C. § 119(a), this application claims the benefit of an earlier filing date and right of priority to Korean Patent Application No. 10-2024-0193950, filed on Dec. 23, 2024, in the Korean Intellectual Property Office, the contents of which are incorporated by reference herein in their entirety.

### TECHNICAL FIELD

The present disclosure relates to a display apparatus.

### BACKGROUND

Display apparatuses include an active area in which images are displayed and a non-active area formed along an outer edge portion of the active area. The display apparatus requires various additional components, such as a driving integrated circuit (D-IC), a source printed circuit board (S-PCB), etc., in addition to a display panel for displaying a screen.

In the non-active area, additional components may be located, or various connecting components, such as a flexible PCB (F-PCB) for connecting the additional components may be located.

The D-IC is also called a “driving chip” and is classified into a chip on film (COF) type that uses a COF and a chip on glass (COG) type that uses only an F-PCB without using the COF. Hereinafter, the D-IC may be referred to as a driving chip (D-IC).

The COF type needs to connect the D-IC to S-PCB using a plurality of COFs, while, in the COG type, the S-PCB needs to be disposed at a short side of a display apparatus and connected to the D-IC.

### SUMMARY

A chip on glass (COG) type does not use a plurality of chip on films (COFs) like a COF type, but one driving chip is connected to a source printed circuit board (S-PCB) through only one flexible PCB (F-PCB). Accordingly, since the COG type is configured so that a plurality of signals are transmitted from one driving chip (D-IC) to the S-PCB through one F-PCB, there is a problem that heat generation is concentrated on the driving chip (D-IC), resulting in a high heat generation temperature of 20 degrees (° C.) or higher.

Meanwhile, the S-PCB is fixed to a back surface of a heat dissipation sheet using a cover tape. In this case, when using the cover tape, a metal layer formed of a copper (Cu) is used, and there is a problem that, due to the characteristics of the copper (Cu) material, the metal layer also transmits electric signals in addition to temperature transfer, thereby causing a short circuit between circuit components.

To solve the above problems, the inventors of the present disclosure have invented a display apparatus in which it is possible to solve the heat generation problem of the driving chip (D-IC) and the problem of a short circuit between components of the printed circuit board (S-PCB).

Accordingly, embodiments of the present disclosure are directed to a display apparatus that substantially obviates one or more of the problems due to limitations and disadvantages of the related art.

An aspect of the present disclosure is to provide a display apparatus in which it is possible to improve heat dissipation performance of a driving chip (D-IC) and preventing a short circuit between circuit components in a printed circuit board (S-PCB) in a COG type display apparatus.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a driving chip disposed on a display panel in a non-active area, a metal plate may be disposed under the display panel, a bending metal plate may be disposed under the metal plate through a first adhesive layer, a printed circuit board may be disposed under the bending metal plate, one side of a bending insulating layer may be disposed on one side of the bending metal plate, the other side of the bending insulating layer may be disposed under the printed circuit board, and the bending insulating layer may be bent to surround the bending metal plate outward in a bending area. To achieve this, in the display apparatus according to an implementation of the present disclosure, a driving chip may be disposed on a display panel in a non-active area, a metal plate may be disposed under the display panel, a bending metal plate may be disposed under the metal plate through a first adhesive layer, a printed circuit board may be disposed under the bending metal plate, one side of a bending insulating layer may be disposed on one side of the bending metal plate, the other side of the bending insulating layer may be disposed under the printed circuit board, and the bending insulating layer may be bent to surround the bending metal plate outward in a bending area.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 illustrates a front surface of a display apparatus according to an implementation of the present disclosure.

FIG. 2 illustrates a back surface of the display apparatus according to the implementation of the present disclosure.

FIG. 3 is a cross-sectional view illustrating a cross section along line A-A′ in FIG. 2 in the display apparatus according to the implementation of the present disclosure.

FIG. 4 is a cross-sectional view illustrating a bending metal plate and a bending insulating layer according to another implementation of the present disclosure.

FIG. 5 is a cross-sectional view illustrating area B in FIG. 3 in the display apparatus according to the implementation of the present disclosure.

FIG. 6 is a view illustrating an example of a configuration of a printed circuit board according to the implementation of the present disclosure.

FIG. 7 is a view illustrating an example of a configuration of a printed circuit board according to another implementation of the present disclosure.

FIG. 8 is a view illustrating heat flow resistance according to the formation of a through hole in the printed circuit board according to another implementation of the present disclosure.

### DETAILED DESCRIPTION

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, exemplary implementations according to the present disclosure will be described in detail with reference to the accompanying drawings. In the drawings, the same reference numerals are used to denote the same or similar components.

In addition, when a first component is described as being “connected,” “coupled,” or “joined” to a second component, the components may be directly connected or joined, but it should be understood that a third component may be “interposed” between the components, or the components may be “connected,” “coupled,” or “joined” through the third component.

Unless otherwise defined, all terms (including technical and scientific terms) used in the disclosure may be used as meaning commonly understood by those skilled in the art to which the present disclosure pertains. In addition, terms defined in commonly used dictionaries are not construed ideally or excessively unless clearly and specially defined.

Hereinafter, according to implementations of the present disclosure, a display apparatus in which it is possible to improve heat dissipation performance of a driving chip (D-IC), prevent a short circuit between circuit components of a printed circuit board (S-PCB), and prevent lifting in a bending area of a display panel will be described.

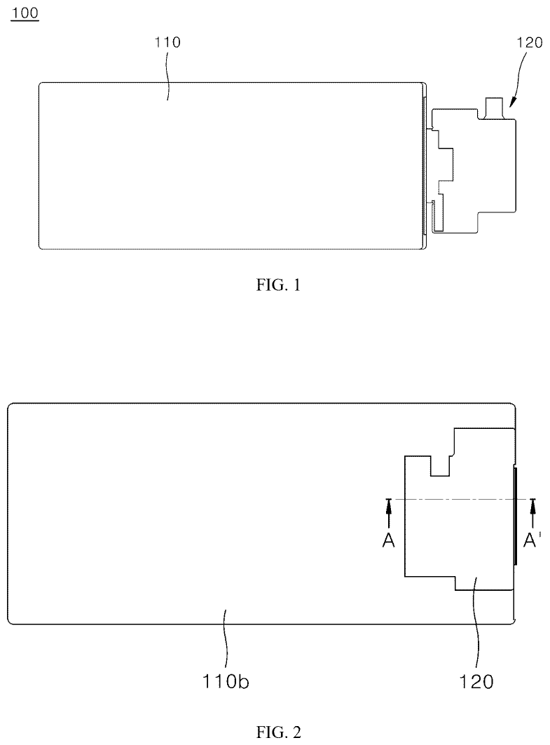

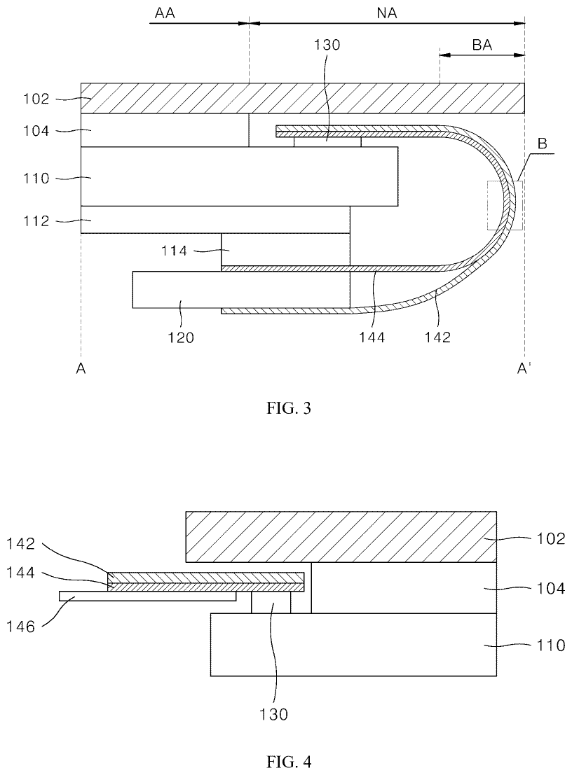

FIG. 1 illustrates a front surface of a display apparatus according to an implementation of the present disclosure. FIG. 2 illustrates a back surface of the display apparatus according to the implementation of the present disclosure. FIG. 3 is a cross-sectional view illustrating a cross section along line A-A′ in FIG. 2 in the display apparatus according to the implementation of the present disclosure.

Referring to FIGS. 1 to 3, a display apparatus 100 according to the implementation of the present disclosure may include a display panel 110 and a printed circuit board 120 (hereinafter referred to as an S-PCB).

The display panel 110 may include an active area AA and a non-active area NA.

The S-PCB 120 may be placed in the non-active area NA. The S-PCB 120 may be bent to a back surface 110b of the display panel 110 and disposed on the back surface 110b of the display panel 110.

The non-active area NA may include a bending area BA. Although not illustrated in the drawings, the non-active area NA may include a bezel area. The bezel area may be disposed along an outermost edge of the display apparatus 100 in a form that surrounds the active area AA. The bending area BA may be located in the bezel area of the display apparatus 100.

The display panel 110 may be referred to as a “flexible substrate.” The display panel 110 may have the active area AA and the non-active area NA that are disposed on the front surface thereof, and the non-active area NA disposed on the back surface 110b.

A driving chip 130 may be disposed on the display panel 110 in the non-active area NA. The driving chip 130 may be disposed on the display panel 110 between the active area AA and the bending area BA. The driving chip 130 may be disposed at an end of the non-active area NA of the display panel 110.

A metal plate 112 may be disposed under the display panel 110. The metal plate 112 may include a metallic material having high thermal conductivity. The metal plate 112 may include, for example, copper (Cu).

A first adhesive layer 114 may be disposed under the metal plate 112. The first adhesive layer 114 may include a fixing tape including an adhesive material.

A bending metal plate 144 may have one side disposed on the driving chip 130 and the other side disposed under the first adhesive layer 114 and may be bent downward in the bending area BA.

The S-PCB 120 may be disposed under the bending metal plate 144.

A bending insulating layer 142 may have one side disposed on the one side of the bending metal plate 144 and the other side disposed under the S-PCB 120 and may be bent to surround the bending metal plate 144 outward in the bending area BA.

In addition, the display apparatus 100 according to the implementation of the present disclosure may further include a second adhesive layer 104 disposed on the display panel 110 in the active area AA, and a cover member 102 disposed in the active area AA and the non-active area NA on the second adhesive layer 104.

The second adhesive layer 104 may include, for example, an optical clear adhesive (OCA).

The cover member 102 may include a cover window and cover glass.

The cover member 102 may be disposed to cover the front surface of the display panel 110 to protect the display panel 110 from an external impact. Although not illustrated in the drawings, an edge portion of the cover member 102 may have a rounded shape that is formed to be curved toward the back surface of the display panel 110. In this case, the cover member 102 may be disposed to cover at least a part of a side surface of the display panel 110 to protect both the front surface and the side surfaces of the display panel 110 from an external impact.

Since the cover member 102 includes the active area AA in which an image is displayed, the cover member 102 may be formed of a transparent material, such as cover glass, to display the image. For example, the cover member 102 may be formed of a transparent plastic, a glass material, or a reinforced glass material.

A front surface of the cover member 20 may be divided into the active area AA and the non-active area NA other than the active area AA. The non-active area NA may be formed along the edge of the active area AA on the front surface of the cover member 102 and, for example, may be defined as a bezel area.

A back surface of the cover member 102 may include the bending area BA. The bezel area may be disposed along the edge of the active area AA on the front surface of the cover member 102. To reduce the bezel area, a radius of curvature of the bending area BA needs to be reduced. The radius of curvature of the bending area BA is proportional to the overall thickness of the display apparatus 100. As the overall thickness increases, the radius of curvature of the bending area BA increases, and as the overall thickness decreases, the radius of curvature of the bending area BA decreases. Accordingly, in order not to increase the size of the bezel area, it is necessary to prevent an increase in the overall thickness of the display apparatus 100.

An upper portion of the driving chip 130 disposed at an end portion of the non-active area NA of the display panel 110 comes into contact with one side of the bending metal plate 144, and the other side of the bending metal plate 144 is bent in the bending area BA and then comes into contact with one surface of the S-PCB 120. Accordingly, the bending metal plate 144 may transfer the heat generated from the driving chip 130 toward the S-PCB 120.

The bending insulating layer 142 may be covered at an outer side of the bending metal plate 144 in the bending area BA.

The bending insulating layer 142 may cover the bending metal plate 144 of the bending area BA and extend to cover the one surface of the S-PCB 120 disposed in the active area AA and the non-active area NA beyond the bending area BA.

The bending insulating layer 142 may include, for example, a resin, and use ultraviolet (UV) curable acrylic-based resin, but is not limited thereto. For example, the bending insulating layer 142 may be formed of a cured product of a resin subjected to a curing process after coated with the resin. When the ultraviolet curing resin is used as the resin, ultraviolet curing may be performed.

The metal plate 112 may include, for example, a metal to support the display panel 110. For example, the metal plate 112 may include one of stainless steel (SUS), copper (Cu), gold (Au), and silver (Ag) or a combination thereof.

The first adhesive layer 114 may include a tape having a shock absorption function or a conductive double-sided tape that is formed in a form including a foam tape or a foam pad. For example, the double-sided conductive tape may include a conductive layer between an upper adhesive layer and a lower adhesive layer, and the adhesive layer may also include a conductive material.

The second adhesive layer 104 may be formed of one or more layers formed of one or more of an optical clear adhesive (OCA), an optical clear resin (OCR), and a pressure sensitive adhesive (PSA).

The cover member 102 protects the display panel 110 from an external impact and transmits the light emitted from the display panel 110 so that the image displayed on the display panel 110 is visible from the outside.

The cover member 102 may be formed of one of poly methyl methacrylate (PMMA), poly carbonate (PC), cycloolefin polymer (COP), polyethylene terephthalate (PET), polyimide (PI), and polyaramid (PA), which have impact resistance and light transmittance. The implementations of the present disclosure are not limited thereto.

The second adhesive layer 104 may have a thickness of, for example, 100 to 300 μm. When the second adhesive layer 104 has a thickness of 100 μm or less, an adhesive strength may be weakened, making it difficult to modularize the cover member 102 and the display panel 110, and when the second adhesive layer 104 has a thickness of 300 μm or more, it may cause a problem that bending is not easy in the display apparatus 100. Accordingly, the second adhesive layer 104 may have a thickness of 100 to 300 μm.

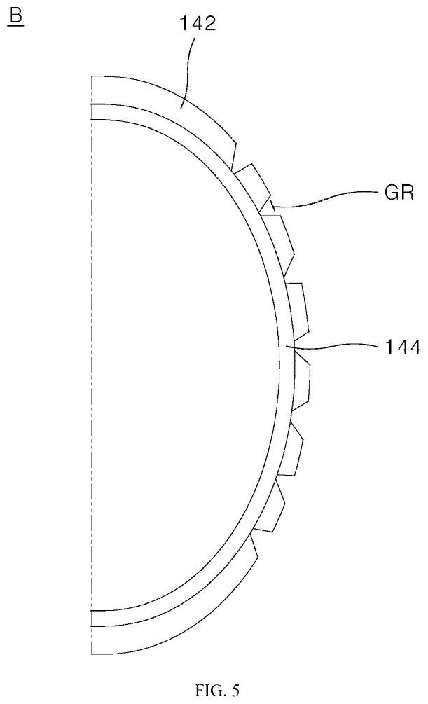

FIG. 4 is a cross-sectional view illustrating a bending metal plate and a bending insulating layer according to another implementation of the present disclosure.

Referring to FIG. 4, in a display apparatus according to another implementation of the present disclosure, the bending metal plate 144 may be disposed on the driving chip 130, the bending insulating layer 142 may be disposed on the bending metal plate 144, and a flexible PCB 146 may be disposed under the bending metal plate 144.

Here, the bending insulating layer 142 may be formed of an inorganic insulation material capable of low-temperature deposition. For example, the bending insulating layer 142 may be silicon nitride (SiNx), silicon oxide (SiOx), silicon oxynitride (SiON), aluminum oxide (Al2O3), etc.

The bending insulating layer 142 may serve as a buffer for relieving stress between layers due to the bending of the display apparatus 100 and also serve to enhance planarization performance. For example, the bending insulating layer 142 may be an acrylic resin, an epoxy resin, polyimide, polyethylene, silicon oxycarbon (SiOC), etc. and formed of an organic insulation material. For example, the bending insulating layer 142 may be formed through an inkjet method.

The bending insulating layer 142 can minimize or block external moisture or oxygen penetrating the bending metal plate 144. For example, the bending insulating layer 142 is formed of an inorganic insulation material, such as silicon nitride (SiNx), silicon oxide (SiOx), silicon oxynitride (SiON), or aluminum oxide (Al2O3).

FIG. 5 is a cross-sectional view illustrating area B in FIG. 3 in the display apparatus according to the implementation of the present disclosure.

Referring to FIG. 5, in the display apparatus according to the implementation of the present disclosure, in area B of FIG. 3, the bending insulating layer 142 covering the outer side of the bending metal plate 144 may have grooves GR formed at regular intervals in the bending area BA.

The bending insulating layer 142 can reduce stress during bending with the formed grooves GR.

The driving chip 130 generates a data signal and a gate control signal based on image data and a timing synchronization signal that are supplied from an external host driving system. In addition, the driving chip 130 may supply a data signal to a data line of each pixel through a pad part and a gate control signal to a gate driving circuit unit (not illustrated).

The driving chip 130 may be mounted in a chip mounting area defined in the display panel 110, electrically connected to the pad part, and connected to signal lines of the gate driving circuit unit and a pixel array unit that are disposed on the display panel 100.

Since the driving chip 130 generates considerable heat, it is necessary to effectively dissipate heat. The driving chip 130 may transfer the generated high heat toward the S-PCB 120 through the bending metal plate 144 and dissipate heat.

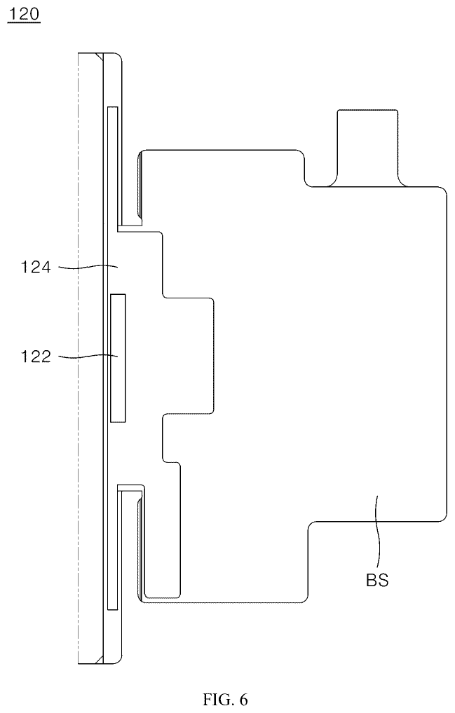

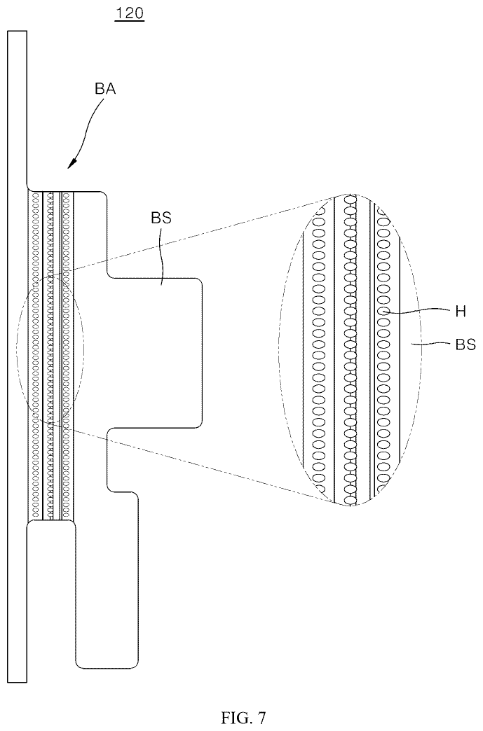

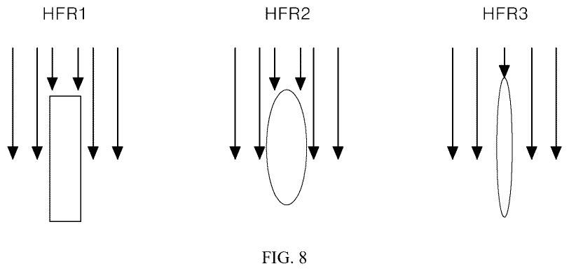

FIG. 6 is a view illustrating an example of a configuration of a printed circuit board according to the implementation of the present disclosure. FIG. 7 is a view illustrating an example of a configuration of a printed circuit board according to another implementation of the present disclosure. FIG. 8 is a view illustrating heat flow resistance according to the formation of a through hole in the printed circuit board according to another implementation of the present disclosure.

Referring to FIG. 6, the S-PCB 120 according to the implementation of the present disclosure may include a chip area 122 corresponding to the driving chip 130, a ground area 124 surrounding the chip area 122, and a base substrate BS.

The driving chip 130 is disposed in the chip area 122, and the ground area 124 provides a path along which electric signals causing a short circuit flow.

Referring to FIG. 7, the S-PCB 120 according to another implementation of the present disclosure may have a plurality of through holes H formed in the base substrate BS in the bending area BA.

In addition, the plurality of through holes H may be formed in the bending insulating layer 142 adhered to the one surface of the S-PCB 120.

In this way, by forming the plurality of through holes H in the base substrate BS or the bending insulating layer 142 of the S-PCB 120, a tensile force generated during bending may be absorbed through the plurality of through holes H.

Referring to FIG. 8, when the bending metal plate 144 and the bending insulating layer 142 are bent or the S-PCB 120 is bent, stretching occurs in a direction in which the tensile force is applied, and tearing may occur due to the stretching, but since the plurality of through holes H absorb the tensile force, it is possible to prevent tearing.

Each of the plurality of through holes H may have an elliptical shape in which a diameter of one side is larger than that of the other side.

When the bending insulating layer 142 and the S-PCB 120 are bent, heat fluid resistance HFR may occur, but the heat fluid resistance HFR can be reduced by the plurality of through holes H having an elliptical shape.

It can be seen that second heat fluid resistance HFR2 and third heat fluid resistance HFR3 in a case in which the plurality of through holes H are elliptical can be reduced more than first heat fluid resistance HFR1 in a case in which the plurality of through holes H are rectangular.

It can be seen that, when the plurality of through holes H are elliptical, the third heat fluid resistance HFR3 having the elliptical shape in which the diameter of one side is larger than that of the other side can be reduced more than the second heat fluid resistance HFR2 having a smaller elliptical shape.

The display apparatus 100 according to the implementation of the present disclosure indicates a flexible display apparatus and may be used with the same meaning as a bendable display apparatus, a rollable display apparatus, an unbreakable display apparatus, a foldable display apparatus, etc.

The driving chip 130 may be implemented as a thin film transistor (TFT) in the non-active area NA. The driving chip 130 may be referred to as a gate-in-panel (GIP) circuit unit. The GIP circuit unit (GIP) may include a gate driver having a GIP structure, and in this case, the gate driver is formed of a bottom gate type thin film transistor BG-T, and source and drain metal films of a bridge line may extend and may be connected to a drain electrode of the BG thin film transistor.

In addition, some components, such as a data driver IC, may be mounted on the separated printed circuit board 120 and coupled to connection interfaces (pads/bumps, pins, etc.) disposed in the non-active area NA using circuit films, such as a COG. Since the non-active area NA may be bent along with the connection interfaces, the printed circuit (COG, etc.) may be located on the rear surface (or the back surface) of the display apparatus 100.

The display apparatus 100 according to the present disclosure may include various additional elements for generating various signals or driving pixels in the active area AA. Additional elements for driving the pixels may include an inverter circuit, a multiplexer, an electrostatic discharge circuit, etc. The display apparatus 100 according to the present disclosure may also include additional elements associated with functions other than pixel driving. For example, the display apparatus 100 according to the present disclosure may include additional elements for providing a touch detection function, a user authentication function (e.g., fingerprint recognition), a multi-level pressure detection function, a tactile feedback function, etc. The above additional elements may be located in the non-active area NA and/or an external circuit connected to the connection interface.

Various parts of the display apparatus 100 according to the present disclosure may be bent along a bending line. The bending line may extend horizontally, vertically, or diagonally. Accordingly, the display apparatus 100 according to the implementation of the present disclosure may be bent in a combination of horizontal, vertical, and diagonal directions based on a required design.

One or more edges of the display apparatus 100 according to the present disclosure may be bent away from a central portion along the bending line. The bending line may be located close to the edge of the display apparatus 100, but may extend across the central portion or extend diagonally from one or more corners of the display apparatus 100. Such a structure may allow the display apparatus 100 to be a foldable display apparatus or a display apparatus for displaying images on both folded surfaces.

Since one or more portions of the display apparatus 100 may be bent, the display apparatus 100 according to the present disclosure can be defined as a substantially flat portion and a bent portion. A part of the display apparatus 100 may be referred to as a substantially flat surface area. A part of the display apparatus 100 may be bent at a predetermined angle, and such a portion may be referred to as a bending area or a curvature area. The curvature area includes a bent section that is actually bent with a predetermined bending radius.

The term “substantially flat” also includes a portion that are not perfectly flat. For example, a concave central portion and a convex central portion may also be described as substantially flat portions in some implementations. One or more bent portions are present next to the concave central portion or the convex central portion and are bent inward or outward at an angle with respect to a bending axis along the bending line. A bending radius of the curvature area is smaller than a bending radius of the flat surface area. That is, the term “substantially flat portion” indicates a portion that has a smaller curvature than that of adjacent sections.

According to the location of the bending line, while a portion at one side of the bending line is located toward the center of the display apparatus 100, a portion at the other side of the bending line is located toward the edge of the display apparatus 100. The portion disposed toward the center of the display apparatus 100 may be described as a central portion, and the portion located toward the edge of the display apparatus 100 may be described as an edge portion. In some cases, the central portion of the display apparatus 100 may be substantially flat and the edge portion thereof may be a bent portion. The substantially flat portion may also be located on the edge portion. In addition, in some shapes of display apparatus 100, the bent section may be disposed between two substantially flat portions.

When the non-active area NA is bent, the non-active area NA may be invisible or only minimally visible from the front surface of the display apparatus 100. A part of the non-active area NA, which is visible from the front surface of the display apparatus 100, may be covered by a bezel. The bezel may be a stand-alone structure or may be formed of a housing or other suitable elements. The part visible from the front surface of the display apparatus 100 of the non-active area NA may be hidden under an opaque mask layer, such as black ink (e.g., a polymer filled with carbon black). Such an opaque mask layer may be provided on any layer (a touch sensor layer, a polarizing layer, a particle cover layer, etc.) included in the display apparatus 100.

In some implementations, the bent portion of the display apparatus 100 may include the active area in which an image may be displayed. That is, the bending line may be disposed in the active area so that at least some pixels of the active area are included in the bent portion.

Meanwhile, the display apparatus 100 according to the implementation of the present disclosure may include the display panel 110 and a display driving circuit.

The display driving circuit is a circuit for driving the display panel 110 and may include a data driving unit, a gate driving unit, a control unit, etc.

The display apparatus 100 according to the implementations of the present disclosure may be a liquid crystal display apparatus, etc. or a light-emitting display apparatus in which the display panel 110 itself emits light. When the display apparatus 100 according to the implementations of the present disclosure is a self-luminous display apparatus, each of a plurality of sub-pixels may include a light-emitting element.

For example, the display apparatus 100 according to the implementations of the present disclosure may be an organic light-emitting display apparatus in which the light-emitting element is implemented as an organic light-emitting diode (OLED). As another example, the display apparatus 100 according to the implementations of the present disclosure may be an inorganic light emitting display apparatus in which the light-emitting element is implemented as an inorganic material-based light-emitting diode. As still another example, the display apparatus 100 according to the implementations of the present disclosure may be a quantum dot display apparatus in which the light-emitting element is implemented as quantum dots that are semiconductor crystals that emits light by themselves.

A structure of each of the plurality of sub-pixels may vary according to the type of the display apparatus 100. For example, when the display apparatus 100 is a self-luminous display apparatus in which the sub-pixel emits light by itself, each sub-pixel may include a light-emitting element that emits light by itself, one or more transistors, and one or more capacitors.

For example, various types of signal lines may include a plurality of data lines that transmit data signals (also referred to as data voltages or image signals), a plurality of gate lines that transmit gate signals (also referred to as scan signals), etc.

The plurality of data lines may intersect the plurality of gate lines. Each of the plurality of data lines may be disposed to extend in a first direction. Each of the plurality of gate lines may be disposed to extend in a second direction.

Here, the first direction may be a column direction, and the second direction may be a row direction. The first direction may be the row direction, and the second direction may be the column direction.

The data driving unit is a circuit configured to drive a plurality of data lines and may output data signals to a plurality of data lines. The data driving unit may supply the data voltages to the display panel 110.

The gate driving unit is a circuit configured to drive a plurality of gate lines and may output gate signals to the plurality of gate lines. The gate driving unit may supply the gate signals to the display panel 110.

The control unit may be a device configured to control the data driving unit and the gate driving unit. The control unit may control a driving timing for the plurality of data lines and a driving timing for the plurality of gate lines.

The control unit may supply a gate driving control signal to the gate driving unit to control the gate driving unit.

The control unit may receive input image data from a host system and supply image data (Data) to the data driving unit based on the input image data.

The data driving unit may supply data signals to the plurality of data lines according to the driving timing control of the control unit.

The data driving unit may receive digital image data (Data) from the control unit, convert the received image data (Data) into analog data signals, and output the analog data signals to the plurality of data lines.

The gate driving unit may supply gate signals to the plurality of gate lines according to the timing control of the control unit. The gate driving unit may receive a first gate voltage corresponding to a turn-on level voltage and a second gate voltage corresponding to a turn-off level voltage along with various gate driving control signals, generate the gate signals, and supply the generated gate signals to the plurality of gate lines.

For example, the data driving unit may be connected to the display panel 110 using a tape automated bonding (TAB) method, connected to the display panel 110 using a COG or chip on panel (COP) method, or connected to a bonding pad of the display panel 110 using a COF method.

The gate driving unit may be connected to the display panel 110 using the TAB method or connected to the bonding pad of the display panel 110 using the COG method or the COP method. Alternatively, the gate driving unit may be formed in the non-active area NA of the display panel 110 in a GIP type. The gate driving unit may be disposed on the substrate or connected to the substrate. That is, when the gate driving unit is the GIP type, the gate driving unit may be disposed in the non-active area NA of the substrate. The gate driving unit may be connected to the substrate when it is the COG type, etc.

Meanwhile, a driving circuit of at least one of the data driving unit and the gate driving unit may be disposed in the active area AA of the display panel 110. For example, the driving circuit of at least one of the data driving unit and the gate driving unit may be disposed so as not to overlap the sub-pixels or disposed to partially or completely overlap the sub-pixels.

The data driving unit may be connected to one side (e.g., an upper side or lower side) of the display panel 110. The date driving unit may be connected to both sides (e.g., the upper side and the lower side) of the display panel 110 or connected to two or more of four side surfaces of the display panel 110 according to a driving method, a panel design method, etc.

The gate driving unit may be connected to one side (e.g., a left side or right side) of the display panel 110. The gate driving unit may be connected to both sides (e.g., the left and right sides) of the display panel 110 or connected to two or more of four side surfaces of the display panel 110 according to a driving method, a panel design method, etc.

The control unit may be implemented as a separate component from the data driving unit or implemented as an integrated circuit integrated with the data driving unit.

The control unit may be a timing controller used in a typical display technology, a control device capable of further performing other control functions other than the timing controller, a control device different from the timing controller, or a circuit in the control device. The control unit may be implemented as various circuits or electronic components, such as an integrated circuit (IC), a field programmable gate array (FPGA), an application specific integrated circuit (ASIC), a processor, etc.

The control unit may be electrically connected to the data driving unit and the gate driving unit through a PCB, a flexible PCB (FPCB), etc.

The control unit may transmit and receive signals to and from the data driving unit according to one or more predetermined interfaces. Here, for example, the interface may include a low voltage differential signaling (LVDS) interface, an embedded panel interface (EPI), a serial peripheral interface (SPI), etc.

To provide both an image display function and a touch sensing function, the display apparatus 100 according to the implementations of the present disclosure may include a touch sensor, and a touch sensing circuit for detecting whether touch has been caused by a touch object, such as a finger or a pen, or detecting a touch location by sensing the touch sensor.

The touch sensing circuit may include a touch driving circuit for driving and sensing the touch sensor and generating and outputting touch sensing data, a touch controller for sensing the occurrence of touch or detecting the touch location using the touch sensing data, etc.

The touch sensor may include a plurality of touch electrodes. The touch sensor may further include a plurality of touch lines for electrically connecting a plurality of touch electrodes to the touch driving circuit.

The touch sensor may be present outside the display panel 110 in the form of a touch panel or present inside the display panel 110.

When the touch sensor is present outside the display panel 110 in the form of a panel, the touch sensor is referred to as an external type touch sensor. When the touch sensor is an external type, the touch panel and the display panel 110 may be manufactured separately and coupled during the assembly process. The external type touch panel may include a touch panel substrate and a plurality of touch electrodes disposed on the touch panel substrate.

When the touch sensor is present inside the display panel 110, the touch sensor may be formed on the substrate along with signal lines, electrodes, etc. related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

When the touch sensing circuit performs touch sensing using the self-capacitance sensing method, the touch sensing circuit may perform the touch sensing based on a capacitance between each touch electrode and the touch object (e.g., a finger or a pen).

According to the self-capacitance sensing method, each of the plurality of touch electrodes may serve as both a driving touch electrode and a sensing touch electrode. The touch driving circuit may drive all or some of the plurality of touch electrodes and sense all or some of the plurality of touch electrodes.

When the touch sensing circuit performs the touch sensing using the mutual-capacitance sensing method, the touch sensing circuit may perform the touch sensing based on the capacitance between the touch electrodes.

According to the mutual-capacitance sensing method, the plurality of touch electrodes are divided into driving touch electrodes and sensing touch electrodes. The touch driving circuit may drive the driving touch electrodes and sense the sensing touch electrodes.

The touch driving circuit and touch controller included in the touch sensing circuit may be implemented as separate devices or implemented as a single device. In addition, the touch driving circuit and the data driving circuit may be implemented as separate devices or implemented as a single device.

The display apparatus 100 according to the implementations of the present disclosure may further include a power supply circuit for supplying various types of power to the display driving circuit and/or the touch sensing circuit, etc.

The display apparatus 100 according to the implementations of the present disclosure may be a mobile terminal, such as a smartphone, a tablet, etc., a monitor or a TV having various sizes, etc., and is not limited thereto, and may be a display apparatus having various types and sizes, which may display information or images.

As described above, according to the implementations of the present disclosure, it is possible to implement the display apparatus in which it is possible to solve the heat generation problem of the driving chip (D-IC) and the problem of a short circuit between components of the printed circuit board (S-PCB).

In addition, according to the implementations of the present disclosure, it is possible to improve heat dissipation performance of the driving chip (D-IC) and preventing a short circuit between circuit components in the printed circuit board (S-PCB) in the COG type display apparatus.

According to the implementations of the present disclosure, since the bending metal plate formed of a copper (Cu) material having high thermal conductivity is bonded to the driving chip (D-IC), the heat generation of the driving chip can be transferred to the back surface through the bending metal plate, thereby improving heat dissipation performance.

In addition, according to the implementations of the present disclosure, since the bending insulating layer is disposed to surround the bending metal plate from the outside, heat radiation transfer to the area corresponding to the back surface of the cover glass (CG) can be blocked through the bending insulating layer, thereby improving heat dissipation performance.

In addition, according to the implementations of the present disclosure, since grooves are formed at regular intervals in the bending insulating layer of the bending area, it is possible to reduce internal stress that causes a repulsive force, thereby securing lifting prevention and attaching process capability.

In addition, according to the implementations of the present disclosure, since the ground area is disposed on the printed circuit board (S-PCB), even when electric signals are transmitted through the bending metal plate, the electric signals can move to the ground area, thereby preventing a short circuit between circuit components.

In addition, according to the implementations of the present disclosure, it is possible to improve the heat dissipation performance of the display panel and prevent lifting due to a decrease in bending stress, thereby preventing a reduction in the life of the display panel.

In addition, according to the implementations of the present disclosure, it is possible to prevent a short circuit in the printed circuit board (S-PCB) of the display panel, improve heat dissipation performance, and preventing lifting, thereby providing the long-life and low-power display apparatus.

In addition, according to the implementations of the present disclosure, it is possible to prevent a short circuit between circuit components and prevent lifting, thereby improving the quality of the display apparatus.

Effects of the present disclosure are not limited to the above-described effects, and other effects that are not described will be able to be clearly understood by those skilled in the art based on the following description.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

### DESCRIPTION OF REFERENCE NUMERALS

100: display apparatus 110: display panel
120: S-PCB 130: driving chip
142: bending insulating layer 144: bending metal layer
112: metal plate 114: first adhesive layer
102: cover member 104: second adhesive layer
146: flexible PCB AA: active area
NA: non-active area BA: bending area

What is claimed is:

1. A display apparatus comprising:
a display panel including an active area and a non-active area;
a driving chip disposed on the display panel in the non-active area;
a metal plate disposed under the display panel;
a first adhesive layer disposed under the metal plate;
a bending metal plate of which one side is disposed on the driving chip and the other side is disposed under the first adhesive layer and which is bent in a bending area;
a printed circuit board disposed under the bending metal plate; and
a bending insulating layer of which one side is disposed on one side of the bending metal plate and the other side is disposed under the printed circuit board and which is bent to surround the bending metal plate outward in the bending area.

2. The display apparatus of claim 1, wherein the bending insulating layer has grooves formed at regular intervals in the bending area.

3. The display apparatus of claim 1, wherein the metal plate includes copper (Cu).

4. The display apparatus of claim 1, wherein the first adhesive layer includes a fixing tape.

5. The display apparatus of claim 1, further comprising:
a second adhesive layer disposed on the display panel in the active area; and
a cover member disposed in the active area and the non-active area on the second adhesive layer.

6. The display apparatus of claim 1, wherein the printed circuit board includes a chip area corresponding to the driving chip, a ground area surrounding the chip area, and a base substrate.

7. The display apparatus of claim 1, wherein the printed circuit board has a plurality of through holes (H) formed in a base substrate in the bending area.

8. The display apparatus of claim 7, wherein each of the plurality of through holes (H) has an elliptical shape in which a diameter of one side is larger than that of the other side.
